(19) United States
(12) Patent Application Publication
(10) Pub. No.: US 2025/0017001 A1
(43) Pub. Date: Jan. 9, 2025

(54) NOVEL STORAGE GATE FINFET FOR NON-VOLATILE MEMORY

(71) Applicant: Taiwan Semiconductor Manufacturing Company, Ltd., Hsinchu (TW)

(72) Inventor: Wen-Chao Shen, Hsinchu (TW)

(21) Appl. No.: 18/348,343

(22) Filed: Jul. 6, 2023

(51) Int. Cl. H10B 20/25; H01L 29/66; H01L 29/78

(52) U.S. Cl. CPC H10B 20/25; H01L 29/66545; H01L 29/66795; H01L 29/7851

(57) ABSTRACT

A non-volatile memory (NVM) device. The NVM device includes: a semiconductor substrate having a plurality of fin-type structures; a select transistor formed on the semiconductor substrate, the select transistor including a gate layer disposed over a first dielectric isolation layer positioned over a first section of the plurality of fin-type structures, where the select transistor is a P-channel metal oxide semiconductor transistor; a storage device formed on the semiconductor substrate, the storage device including a storage gate layer disposed over a second dielectric isolation layer positioned over a second section on the plurality of fin-type structures, where the storage gate layer is arranged to trap charges, and where the storage device is a P-channel storage device, where the select transistor is coupled to the storage device; and the first section of the plurality of fin-type structures is adjacent to the second section of the plurality of fin-type structures.

### FIELD

Embodiments of the present disclosure relate generally to memory devices, and more particularly to novel storage gate fin-field effect transistors (FINFET) used for non-volatile memory (NVM) that are employed in embedded applications.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B illustrate an OTP cell, in accordance with some embodiments. FIG. 1A shows a plan view of the OTP cell, while FIG. 1B illustrates a cross-sectional view along a first sectional line and a second cross-sectional line of the OTP cell of FIG. 1A.

FIG. 2A shows a schematic representation of the OTP cell of FIG. 1A in an initial non-programmed state. FIG. 2B shows a plan view of the OTP cell of FIG. 1A in a non-programmed state. FIG. 2C illustrates a cross-sectional view along sectional line of the OTP cell of FIG. 1A in a non-programmed state. FIG. 2D shows a schematic representation of the OTP cell of FIG. 1A in a programmed state. FIG. 2E shows a plan view of the OTP cell of FIG. 1A in a programmed state. FIG. 2F illustrates a cross-sectional view along sectional line of the OTP cell of FIG. 1A in a programmed state.

FIGS. 3A to 3E illustrate a method of fabrication of an OTP cell, according to certain embodiments. FIGS. 3A-3E are cross-sectional diagrams illustrating the OTP cell of FIG. 1A at various stages of process, in accordance with some embodiments.

FIG. 4 is a flowchart diagram illustrating an example method for fabricating an OTP cell of FIGS. 3A-3E in accordance with some embodiments.

FIGS. 5A to 5E illustrate an alternate method of fabrication of an OTP cell, according to certain embodiments. FIGS. 5A-5E are cross-sectional diagrams illustrating the OTP cell of FIG. 1A at various stages of process, in accordance with some embodiments.

FIG. 6 is a flowchart diagram illustrating an example method for fabricating an OTP cell of FIGS. 5A-5E in accordance with some embodiments.

FIGS. 7A and 7B illustrate a NOR-type memory array arrangement using an OTP cell of FIG. 1A, according to certain embodiments. FIG. 7A illustrates a plan view of a NOR-type memory cell utilizing the OTP cell, according to certain embodiments. FIG. 7B shows a schematic diagram illustrating the memory cell array in accordance with some embodiments.

FIGS. 8A and 8B illustrate read and program operation of the NOR-type memory cell of FIGS. 7A and 7B, according to certain embodiments.

FIGS. 9A and 9B illustrate an AND-type memory array arrangement using an OTP cell, according to certain embodiments. FIG. 9A illustrates a plan view of a AND-type memory cell utilizing an OTP cell, according to certain embodiments. FIG. 9B shows a schematic diagram illustrating the AND-type memory cell in accordance with some embodiments.

### DETAILED DESCRIPTION OF THE INVENTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, source/drain region(s) may refer to a source or a drain, individually or collectively dependent upon the context. For example, a device may include a first source/drain region and a second source/drain region, among other components. The first source/drain region may be a source region, whereas the second source/drain region may be a drain region, or vice versa. One of ordinary skill in the art would recognize many variations, modifications, and alternatives.

Some embodiments of the disclosure are described. Additional operations can be provided before, during, and/or after the stages described in these embodiments. Some of the stages that are described can be replaced or eliminated for different embodiments. Some of the features described below can be replaced or eliminated and additional features can be added for different embodiments. Although some embodiments are discussed with operations performed in a particular order, these operations may be performed in another logical order.

Non-volatile memory (NVM) or non-volatile storage is a type of computer memory that can retain stored information even after the power supply is removed. In contrast, volatile memory needs constant power in order to retain data. Non-volatile memory is typically used for the task of secondary storage or long-term persistent storage.

Non-volatile memory includes, among other types, flash memory devices, ferroelectric random-access memory (FeRAM or FRAM) devices, magnetoresistive random-access memory (MRAM) devices, phase-change memory (PCRAM or PCM), resistive random-access memory (RRAM or ReRAM).

Flash memory is one kind of non-volatile memory. Flash memory is a solid-state memory device that maintains stored data without any external power source. Flash memory devices use two different technologies, namely NOR and NAND (named for the NOR and NAND logic gates), to map data. Both use the same cell design, consisting of floating gate metal-oxide-semiconductor field-effect transistors (MOSFETs). They differ at the circuit level depending on whether the state of the bit line or word lines is pulled high or low: in NAND flash, the relationship between the bit line and the word lines resembles a NAND gate; in NOR flash, it resembles a NOR gate.

NOR flash memory devices provide high-speed random access, reading and writing data in specific memory locations; they can retrieve as little as a single byte. NAND flash memory devices read and write sequentially at high speed, handling data in blocks. However, NAND flash memory devices are slower on read when compared to NOR flash memory devices. NAND flash memory devices read faster than they write, quickly transferring whole pages of data. Less expensive than NOR flash memory devices at high densities, NAND technology offers higher capacity for the same-size silicon.

In current approaches, non-volatile memory may utilize floating poly silicon (also referred to as poly) gate to storage charges. As technology shrinks, thin gate oxide and metal gate process can become a bottleneck for reliable non-volatile memory, particularly for data retention. Embodiments of the present disclosure can utilize a cut metal gate process to fabricate a select transistor coupled to a storage device, where the storage element can have a gate formed from a dielectric, such as, but not limited to, silicon nitride (SiN). Storage device may also be referred to as a storage element. This can provide a suitable storage element for NVM used in applications such as, but noy limited to, embedded NVM (eNVM). Moreover, the disclosed fabrication process is compatible with CMOS FINFET processes. In the disclosed cut metal gate process, metal regions can be removed to provide isolation for the gate of the select transistor. Further, some metal regions can be removed and filled by a dielectric, such as SiN or a multilayered structure including silicon nitride layer and silicon oxide layer, to form a storage element. The storage gate can be arranged to trap and store charges such that the storage element can operate as a one-time programmable device. As appreciated by one of ordinary skill in the art having the benefit of this disclosure, other type of dielectric material may be used to form the gate of the storage element.

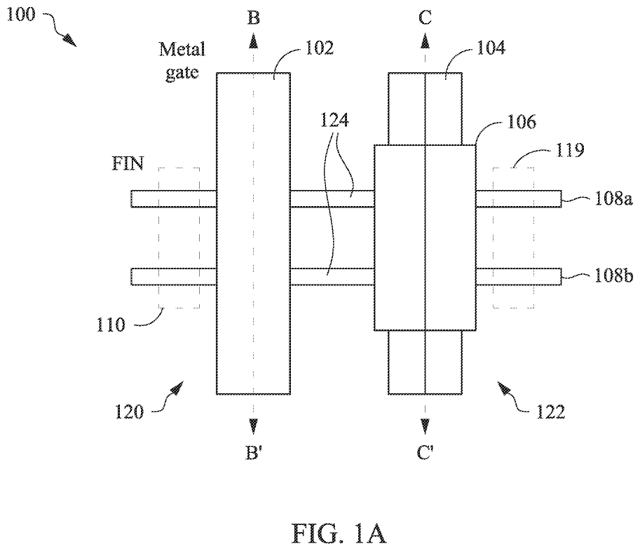

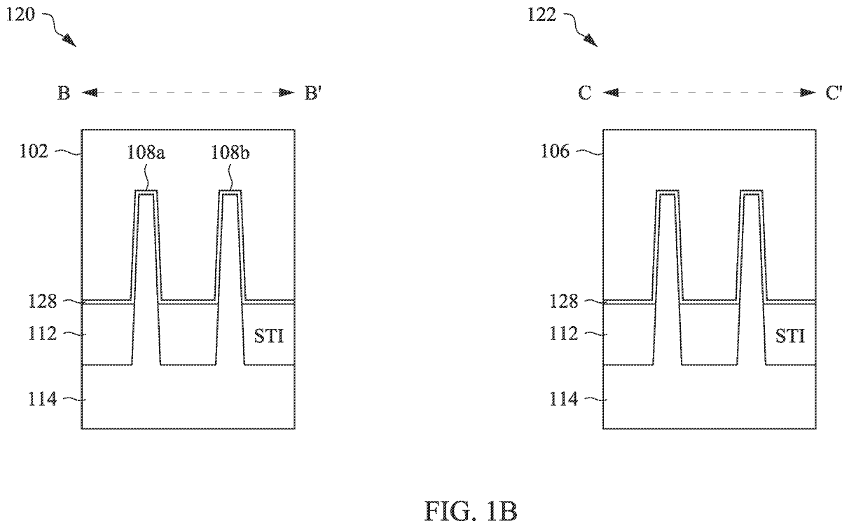

In accordance with some aspects of the disclosure, a select transistor coupled to a storage gate FINFET device that can store charges is provided. The select transistor along with the storage gate storage device can be utilized in a one-time-programmable (OTP) cell of a NOR-type or AND-type memory cell array. In some embodiments, the storage gate may include a silicon nitride (SiN) gate. In various embodiments, the storage gate may include multilayered structure including silicon nitride layer and silicon oxide layer. The select transistor can a p-channel transistor and the Storage gate storage device can be a p-channel device also. The OTP cell can be programmed by channel hot hole induced hot electrons (CHHIHE) under low voltage operation. In addition, methods of fabrication of the OTP cell are provided in accordance with some aspects of the disclosure. The methods of fabrication of the OTP cell can include cut-metal techniques. Details of various aspects of the disclosure will be described below with reference to FIGS. 1-9.

FIGS. 1A and 1B illustrate an OTP cell 100, in accordance with some embodiments. The OTP cell 100 can include a select transistor 120 and a Storage gate storage device 122. FIG. 1A shows a plan view of the OTP cell 100, while FIG. 1B illustrates a cross-sectional view along sectional lines B-B′ and C-C′ of the OTP cell 100. In the OTP cell 100, the select transistor 120 may be coupled to the Storage gate storage device 122. In some embodiments, the select transistor 120 and the Storage gate storage device 122 can have fin-type structure. The Storage gate storage device may also be referred to as a Storage gate storage device. The Storage gate storage device 122 can be used as a storage element that stores information (e.g., a “logic 0” or a “logic 1”). In some embodiments, the select transistor 120 can be a p-channel transistor. The select transistor 120 can have a source 110, a gate 102 and an intermediate node 124. In various embodiments, the select transistor 120 can include a plurality of fin-type structures. The plurality of fin-type structures can include a first fin 108a and a second fin 108b. The gate 102 of the select transistor 120 may be formed from a metal, such as, but not limited to, tungsten (W), aluminum (Al), titanium nitride (TiN) or tantalum nitride (TaN).

As shown in FIG. 1B, the select transistor 120 can be formed on a semiconductor substrate 114 and can include first and second fins 108a and 108b. The semiconductor substrate can include a semiconductor wafer (such as silicon) or a portion of a semiconductor wafer. In some embodiments, the semiconductor substrate 114 is made of an elementary semiconductor material including silicon or germanium in a single crystal, polycrystal, or amorphous structure. In various embodiments, the semiconductor substrate 114 may include multi-layer semiconductors, semiconductor-on-insulator (SOI) (such as silicon-on-insulator or germanium-on-insulator), or a combination thereof.

The select transistor 120 can include a shallow trench insulator (STI) structure 112 that may partially enclose the first and second fins 108a and 108b. The STI structure 112 can be configured to define, and electrically isolate various device elements (not shown) formed in the semiconductor substrate 114, in accordance with some embodiments. Examples of the various device elements include memory cells, transistors (e.g., metal oxide semiconductor field effect transistors (MOSFET), complementary metal oxide semi-conductor (CMOS) transistors, bipolar junction transistors (BJT), high-voltage transistors, high-frequency transistors, p-channel and/or n-channel field effect transistors (PFETs/NFETs), etc.), diodes, another suitable element, or a combination thereof. Various processes are performed to form the various device elements, such as deposition, etching, implantation, photolithography, annealing, planarization, another applicable process, or a combination thereof.

The STI structure 112 can be made of a dielectric material. The dielectric material may include silicon oxide, silicon nitride, silicon oxynitride, fluoride-doped silicate glass (FSG), a low-K dielectric material, other suitable materials, or combinations thereof, in accordance with some embodiments. The STI structure 112 can be formed by using an isolation technology, such as local oxidation of semiconductor (LOCOS), shallow trench iso-lation (STI), or the like, in accordance with various embodiments. A dielectric layer 128 may be disposed between the gate 102 and the STI structure 112. The dielectric layer 128 may be formed from dielectrics such as, but not limited to, silicon oxide (SiOx), hafnium oxide (HfOx) or zirconium oxide (ZrOx).

In some embodiments, the dielectric layer includes one or more dielectric materials such as a high-κ dielectric material (e.g., HfO₂, HfSiO, HfSiON, HfTaO, HfTiO, HfZrO, zirconium oxide, aluminum oxide, hafnium dioxide-alumina (HfO₂—Al₂O₃) alloy, and the like), semiconductor oxide, semiconductor nitride, semiconductor oxynitride, semiconductor carbide, amorphous carbon, tetraethylorthosilicate (TEOS), other suitable dielectric material, and/or combinations thereof. In some examples, the first dielectric layer includes oxide such as SiO₂, SiAlOₓ, HfO₂, ZrO₂, and the like. In some implementations, the dielectric layer is formed using one of various deposition processes.

The Storage gate storage device 122 can include a gate 104, a Storage gate 106, and a drain 119. The Storage gate storage device 122 can be coupled to the select transistor 120 at the intermediate node 124. The Storage gate 106 may include materials such as, but not limited to, silicon nitride or silicon oxynitrides. As shown in FIG. 1B, the Storage gate storage device 122 can also be formed on the semiconductor substrate 114. The dielectric layer 128 can be disposed between the Storage gate 106 and the STI structure 112. In some embodiments, two different dielectric layers in the select transistor region and in Storage gate storage device region can be formed in order to enable optimizing the characteristics of the select transistor and the storage device separately. In various embodiments, the dielectric layers in the SiN cut metal gate region and in SiN storage gate regions can be formed from the same material. In some embodiments, the dielectric layers in the cut metal gate region and in storage gate regions can be formed from the various material such as, but not limited to, SiN layer and SiO₂ layer.

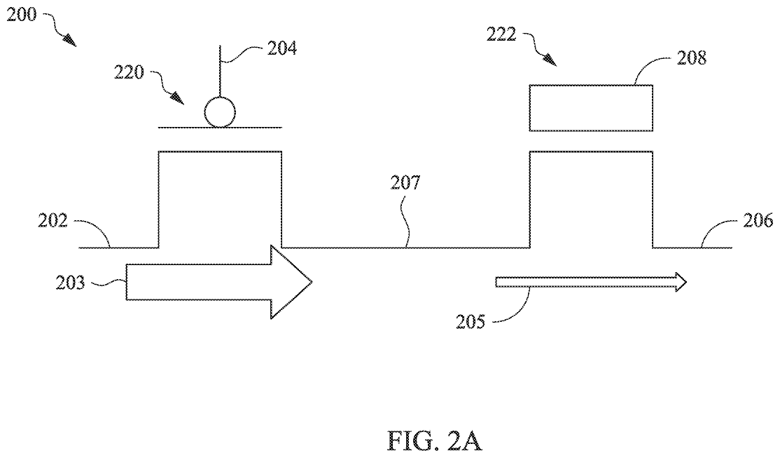

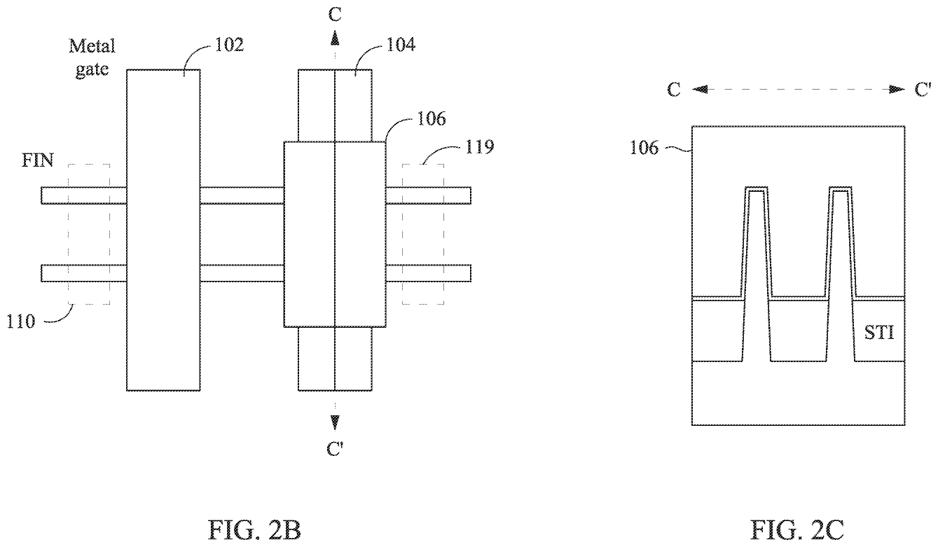

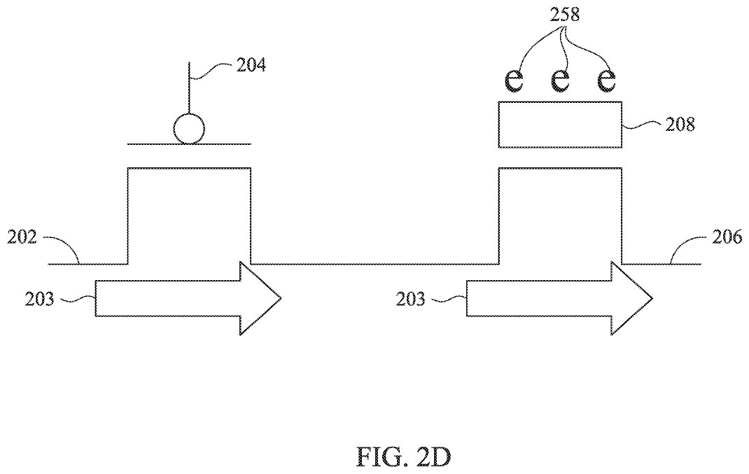

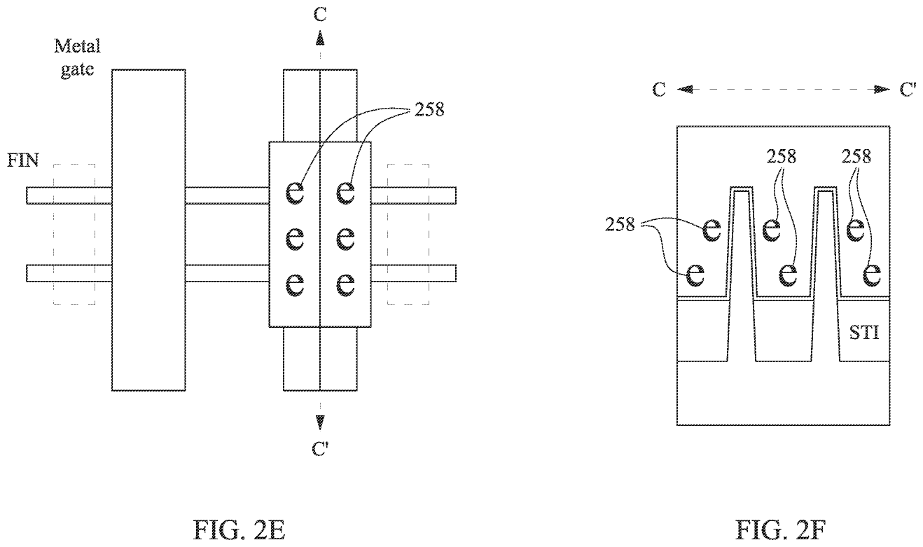

The operation of the OTP cell 100 is now described. FIG. 2A shows a schematic representation 200 of the OTP cell 100. The schematic representation 200 can include a select transistor 220 coupled to a Storage gate storage device 222. The select transistor may also be referred to as a control transistor. In some embodiments, the select transistor can be a PMOS transistor. The select transistor 220 can include a source 202, a gate 204 and an intermediate node 207. The Storage gate storage device 222 can include a Storage gate 208 and a drain 206, where the Storage gate storage device 222 is coupled to the select transistor 220 at the intermediate node 207. FIG. 2A shows an initial state of the OTP cell 100, where the select transistor 220 is ON and a current 203 is flowing from the source 202 to the intermediate node 207. In the initial state, the Storage gate storage device 222 is OFF because there are no charges stored in the gate, therefore a relatively small current 205 may be flowing from the intermediate node 207 to the drain 206. During a programming time period, a sub-threshold current in the storage element can create sufficient number of hot electrons to that can get trapped in the storage gate. During the programming time period, the Storage gate 208 can trap some of the electrons that are created by channel hot hole induced hot electrons.

During the programming time period, a sufficient number of electrons 258 can be trapped in the Storage gate 208 such that the Storage gate storage device 222 can turn ON, as shown in FIG. 2D. The trapped electrons can turn on the channel because the storage element is P-channel. FIG. 2D shows a program state of the OTP cell 100, where the current 203 may be flowing through the select transistor 220 and the Storage gate storage device 222. In various embodiments, the programming time period can be in the range of 0.01 us to 500 us, while in other embodiments the programming time period can be in the range of 0.1 us to 100 us, and in yet other embodiments the programming time period can be in the range of 1 us to 50 us. As appreciated by one of ordinary skill in the art having the benefit of this disclosure, values for programming period can be set to any suitable value.

FIG. 2B shows a plan view of the OTP cell 100, while FIG. 2C illustrates a cross-sectional view along sectional line C-C′ of the OTP cell 100 in the initial state. FIGS. 2B and 2C illustrate the initial state of the OTP cell 100, where there may be no electrons trapped in the Storage gate 106. FIG. 2E shows a plan view of the OTP cell 100, while FIG. 2F illustrates a cross-sectional view along sectional line C-C′ of the OTP cell 100 in the programming state. As can be seen, some electrons 258 may be trapped in the Storage gate 106, such that the Storage gate storage device is programmed to an ON state. As this a permanent programming, the OTP cell 100 is suitable for one-time-programming applications, such as, but not limited to, non-volatile memory. When the storage gate has not been programmed, a current in the storage element is low indicating a logic state 0, while when the storage gate has been programmed, a current in the storage element can be high, indicating a logic 1.

### Fabrication Process

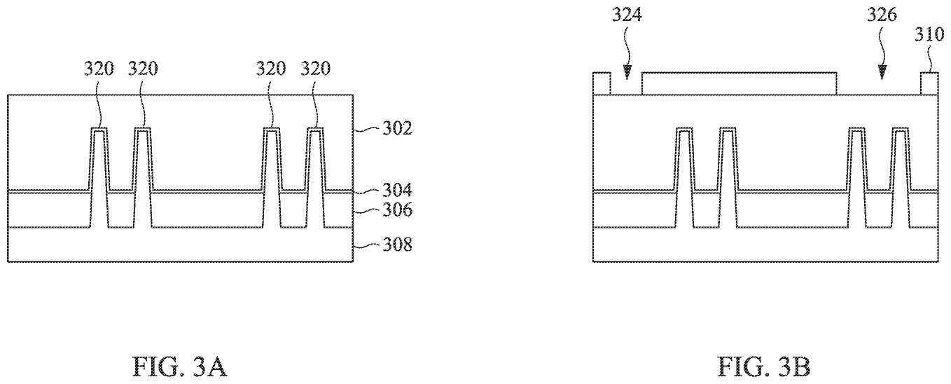

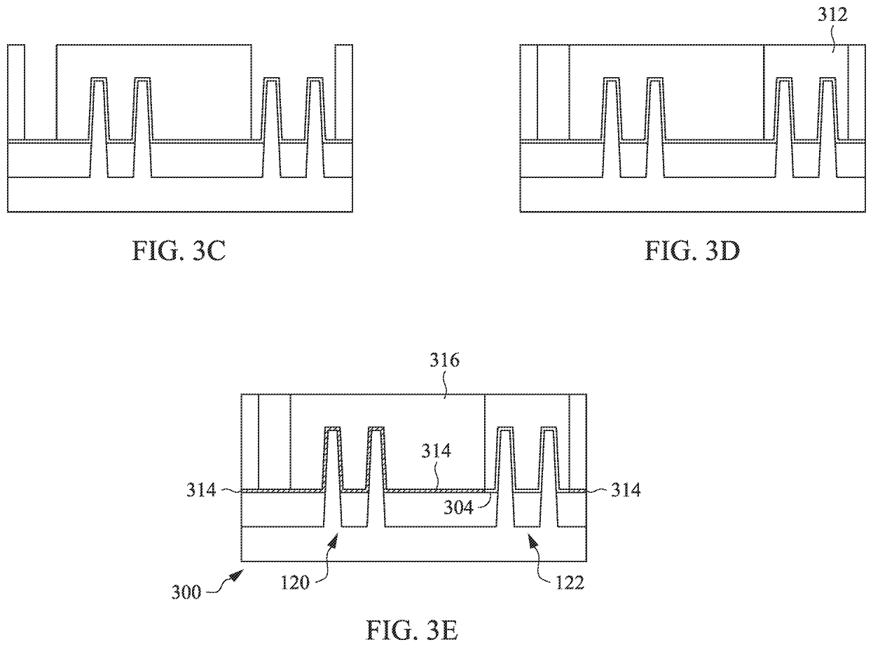

FIGS. 3A to 3E illustrate a method of fabrication of an OTP cell, according to certain embodiments. FIGS. 3A-3E are cross-sectional diagrams illustrating the OTP cell at various stages of process, in accordance with some embodiments. As shown in FIG. 3A, a semiconductor substrate 308 that has been processed to after fin 320 and sacrificial gate 302 formation is provided. The semiconductor wafer 308 can include an STI structure 306, and a first dielectric layer 304 that is disposed between the sacrificial gate 302 and the STI structure 306. The first dielectric layer 304 may be formed from dielectrics such as, but not limited to, silicon oxide (SiOx), hafnium oxide (HfOx) or zirconium oxide (ZrOx).

FIG. 3B illustrates the OTP cell during photo-resist process that can simultaneously define storage cut metal gate and storage gate regions. A photo-resist layer 310 may be deposited on the sacrificial gate 302 and etched to define openings for the cut metal gate region 324 and storage device region 326.

FIG. 3C illustrates the OTP cell after removal of the poly layer in the regions 324 and 326. The removal can be achieved by an etching process. The etching process for forming the trench includes a dry etching process, a wet etching process, a plasma etching process, or a combination thereof, in accordance with some embodiments. FIG. 3D illustrates SiN filling 312 in the regions 324 and 326, followed by planarization to planarize the semiconductor wafer including the filled regions 324 and 326. The filling process includes a chemical vapor deposition process, in accordance with some embodiments. FIG. 3E illustrates a processed OTP cell where the sacrificial gate 302 has been removed and replaced by a metal gate 316, and where the first dielectric layer 304 has been replaced by a second dielectric layer 314 in regions outside of the storage device region 326. In some embodiments, two different dielectric layers in the cut metal gate region and in storage device gate region may be formed in order to enable optimizing the characteristics of the control transistor and the storage element separately.

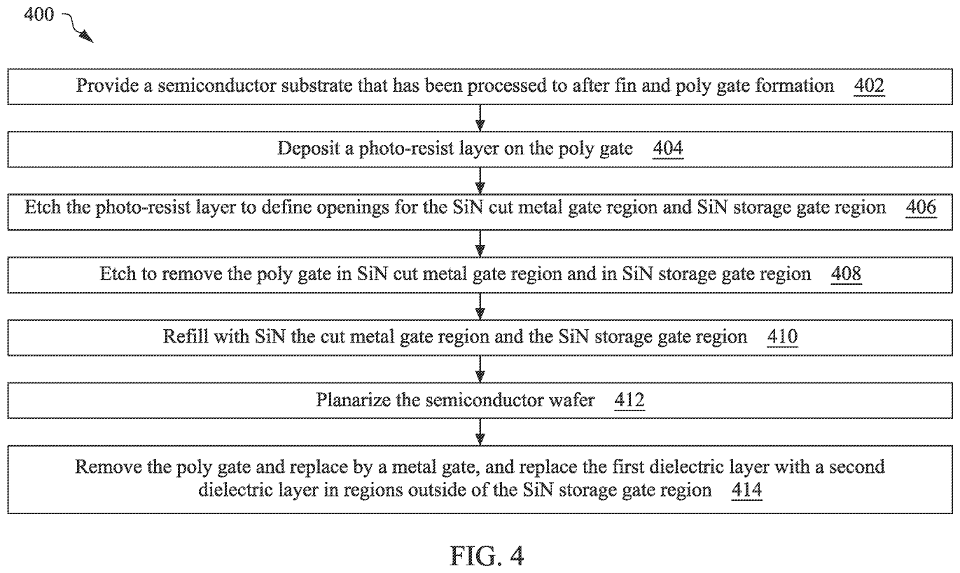

FIG. 4 is a flowchart diagram illustrating an example method 400 for fabricating an OTP cell 300 in accordance with some embodiments. In the example shown in FIG. 4, the method 400 may include operations 402, 404, 406, 408, 410, 412, and 414. Additional operations may be performed. Also, it should be understood that the sequence of the various operations discussed above with reference to FIG. 4 is provided for illustrative purposes, and as such, other embodiments may utilize different sequences. These various sequences of operations are to be included within the scope of embodiments.

At operation 402, a semiconductor substrate is provided that has been processed to after fin and poly gate formation. As mentioned above, the semiconductor substrate can be a silicon substrate in one implementation. It should be understood that other types of substrates may be employed as well in other implementations. It should be understood that other types of gate material may be employed as well in other implementations.

At operation 404, a photo-resist layer can be deposited on the sacrificial gate layer. It should be understood that other types of material may be employed for the gate as well in other implementations.

At operation 406, the photo-resist layer can be etched to define openings for the cut metal gate and storage device regions. At operation 408, the poly gate in the cut metal gate region and in storage device region can be etched. The etching process for forming the trench includes a dry etching process, a wet etching process, a plasma etching process, or a combination thereof, in accordance with some embodiments.

At operation 410, the cut metal gate region and the storage device region can be refilled with a dielectric such, but not limited to, SiN and or a multilayer dielectric including SiN and silicon dioxide. In some embodiments, the cut metal gate region and the storage gate region can be refilled with material such as, but not limited to, SiN, silicon oxynitride, and/or silicon dioxide, or a multilayer structure having SiN and silicon dioxide layers. The filling process includes a chemical vapor deposition process, in accordance with some embodiments.

At operation 412, the semiconductor wafer may be planarized using a planarization process such as a CMP process. In one implementation, the planarization process is a CMP process.

At operation 414, the sacrificial gate can be removed and replaced by a metal gate, and the first dielectric layer can be replaced with a second dielectric in regions outside of the storage gate. The metal gate may be formed from material such as, but not limited to, tungsten (W), aluminum (Al), titanium nitride (TiN) or tantalum nitride (TaN). The second dielectric layer be formed from dielectrics such as, but not limited to, silicon oxide (SiOx), hafnium oxide (HfOx) or zirconium oxide (ZrOx). It should be understood that the method 400 shown in FIG. 4 is one way to fabricate the OTP cell 300, and one of ordinary skill in the art would recognize many variations, modifications, and alternatives.

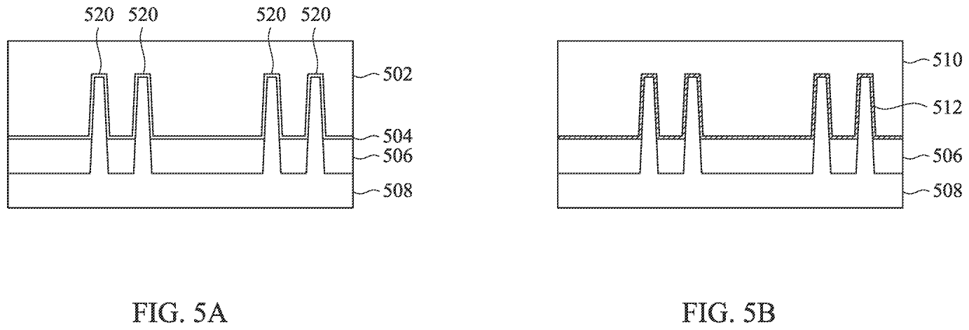

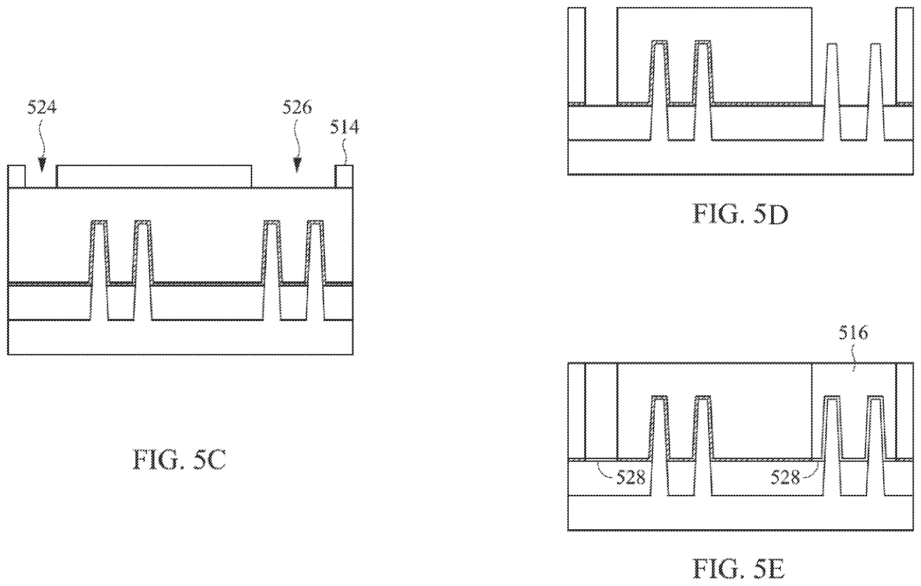

FIGS. 5A to 5E illustrate a method of fabrication of an OTP cell, according to some embodiments. FIGS. 5A-5E are cross-sectional diagrams illustrating the OTP cell at various stages of process, in accordance with some embodiments. As shown in FIG. 5A, a semiconductor wafer 508 that has been processed to after fin 520 and sacrificial gate 502 formation is provided. The semiconductor wafer 508 can include an STI structure 506, and a first dielectric layer 504 that is disposed between the sacrificial gate 502 and the STI structure 506.

In some embodiments, the first dielectric layer 504 can include one or more dielectric materials such as a high-κ dielectric material (e.g., HfO₂, HfSiO, HfSiON, HfTaO, HfTiO, HfZrO, zirconium oxide, aluminum oxide, hafnium dioxide-alumina (HfO₂—Al₂O₃) alloy, and the like), semiconductor oxide, semiconductor nitride, semiconductor oxynitride, semiconductor carbide, amorphous carbon, tetraethylorthosilicate (TEOS), other suitable dielectric material, and/or combinations thereof. In some examples, the first dielectric layer includes oxide such as SiO₂, SiAlOₓ, HfO₂, ZrO₂, and the like. In some implementations, the first dielectric layer is formed using one of various deposition processes.

In the next step, the sacrificial gate 502 can be replaced by a metal gate 510 and the first dielectric layer 504 may be replaced by a second dielectric layer 512, as shown in FIG. 5B. Various processes can be performed to replace the sacrificial gate 502 and the first dielectric layer 504 with the metal gate 510 and the second dielectric layer 512 such as etching, deposition, etching, photolithography, planarization, another applicable process, or a combination thereof. In some embodiments, two different dielectric layers in the SiN cut metal gate region and in SiN storage gate region is formed in order to enable optimizing the characteristics of the control transistor and the storage element separately.

FIG. 5C illustrates the OTP cell during a photo-resist process to simultaneously define cut metal gate and storage device regions. A photo-resist layer 514 may be deposited on the metal gate 510 and etched to define openings for the cut metal gate region 524 and storage device region 526.

FIG. 5D illustrates removal of the metal gate 510 in the regions 524 and 526. This can be performed by an etching process, among others. The etching process for forming the trench includes a dry etching process, a wet etching process, a plasma etching process, or a combination thereof, in accordance with some embodiments. FIG. 5E illustrates dielectric, such as SiN and/or SiN/SiOx, refill 516 of the regions 524 and 526, followed by planarization to planarize the semiconductor wafer including the filled regions 524 and 526. The filling process includes a chemical vapor deposition process, in accordance with some embodiments. A third dielectric 528 may be deposited in the regions 524 and 526. Further, the regions 524 and 526 may be filled by a dielectric such as, but not limited to, SiN. FIG. 5E illustrates the semiconductor wafer 508 where the second dielectric layer 512 has been replaced by a third dielectric 528 in regions 524 and 526.

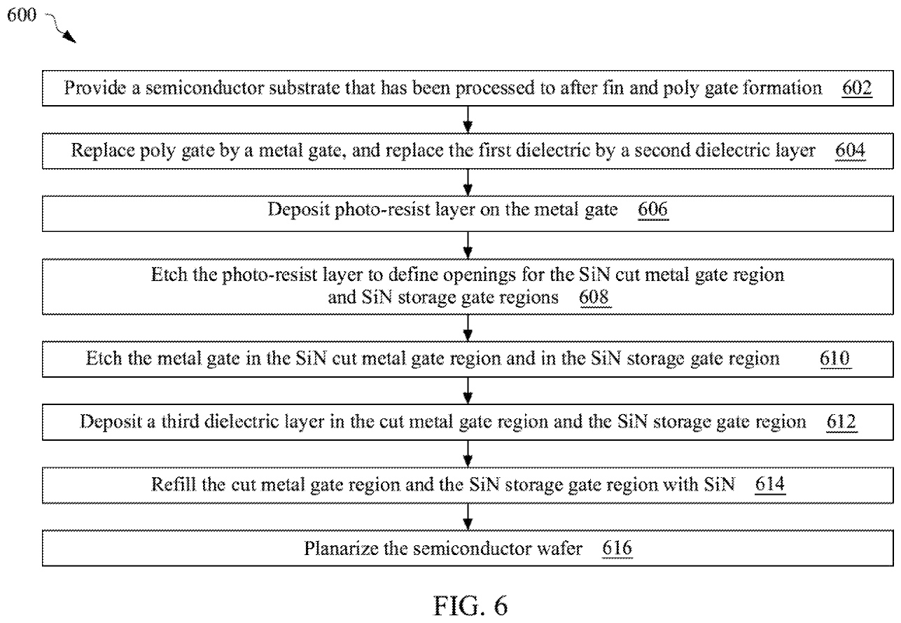

FIG. 6 is a flowchart diagram illustrating an example method 600 for fabricating an OTP cell in accordance with certain embodiments. In the example shown in FIG. 6, the method 600 may include operations 602, 604, 606, 608, 610, 612, 614 and 616. Additional operations may be performed. Also, it should be understood that the sequence of the various operations discussed above with reference to FIG. 6 is provided for illustrative purposes, and as such, other embodiments may utilize different sequences. These various sequences of operations are to be included within the scope of embodiments.

At operation 602, a semiconductor substrate is provided that has been processed to after fin and poly gate formation. As mentioned above, the semiconductor substrate can be a silicon substrate in one implementation. It should be understood that other types of substrates may be employed as well in other implementations. It should be understood that other types of gate material may be employed as well in other implementations. The semiconductor substrate can include an STI structure, and a first dielectric layer that is disposed between the poly gate and the STI structure.

In some embodiments, the first dielectric layer includes one or more dielectric materials such as a high-κ dielectric material (e.g., HfO₂, HfSiO, HfSiON, HfTaO, HfTiO, HfZrO, zirconium oxide, aluminum oxide, hafnium dioxide-alumina (HfO₂—Al₂O₃) alloy, and the like), semiconductor oxide, semiconductor nitride, semiconductor oxynitride, semiconductor carbide, amorphous carbon, tetraethylorthosilicate (TEOS), other suitable dielectric material, and/or combinations thereof. In some examples, the first dielectric layer includes oxide such as SiO₂, SiAlOₓ, HfO₂, ZrO₂, and the like. In some implementations, the first dielectric layer is formed using one of various deposition processes.

At operation 604, the poly gate can be replaced by a metal gate, and a first dielectric can be replaced by a second dielectric layer. In various embodiments, the second dielectric layer includes one or more dielectric materials such as a high-κ dielectric material (e.g., HfO₂, HfSiO, HfSiON, HfTaO, HfTiO, HfZrO, zirconium oxide, aluminum oxide, hafnium dioxide-alumina (HfO₂—Al₂O₃) alloy, and the like), semiconductor oxide, semiconductor nitride, semiconductor oxynitride, semiconductor carbide, amorphous carbon, tetraethylorthosilicate (TEOS), other suitable dielectric material, and/or combinations thereof. In some examples, the first dielectric layer includes oxide such as SiO₂, SiAlOₓ, HfO₂, ZrO₂, and the like. In some implementations, the first dielectric layer is formed using one of various deposition processes.

At operation 606, a photo-resist layer can be deposited on the metal gate. It should be understood that other types of gate material may be employed as well in other implementations.

At operation 608, the photo-resist layer can be etched to define openings for the SiN cut metal gate region and SiN storage gate regions.

At operation 610, the metal gate in SiN cut metal gate region and in SiN storage gate region can be etched. The etching process for forming the trench includes a dry etching process, a wet etching process, a plasma etching process, or a combination thereof, in accordance with some embodiments.

At operation 612, a third dielectric layer can be deposited in the cut metal gate region and the SiN storage gate regions. In another implementation, the first oxide layer may be deposited using chemical vapor deposition (CVD). In yet another implementation, the first oxide layer may be deposited using atomic layer deposition (ALD). In some embodiments, two different dielectric layers in the SiN cut metal gate region and in SiN storage gate region is formed in order to enable optimizing the characteristics of the control transistor and the storage element separately.

At operation 614, the cut metal gate region and the SiN storage gate region can be refilled with SiN. In some embodiments, the cut metal gate region and the SiN storage gate region can be refilled with SiN and/or silicon oxynitride. The filling process includes a chemical vapor deposition process, in accordance with some embodiments.

At operation 616, the semiconductor wafer may be planarized using a planarization process such as a CMP process. In one implementation, the planarization process is a CMP process.

It should be understood that the method 600 shown in FIG. 6 is one way to fabricate the OTP cell, and one of ordinary skill in the art would recognize many variations, modifications, and alternatives.

### Operation

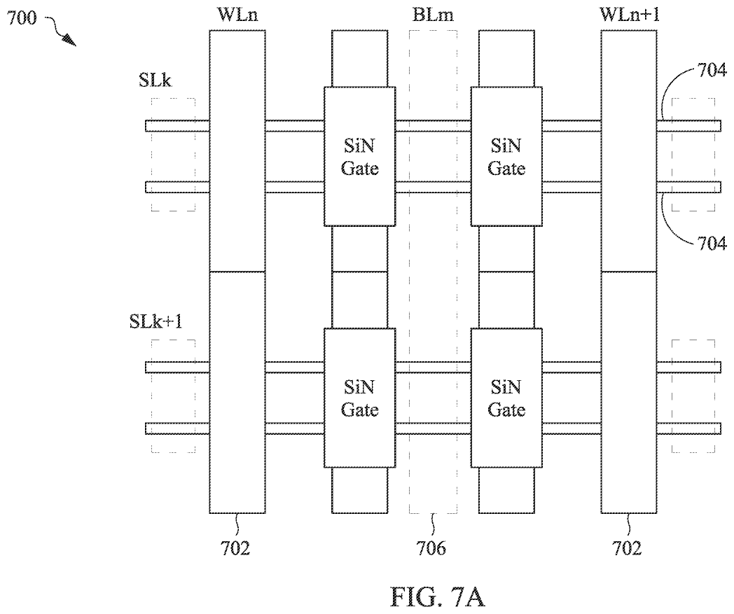

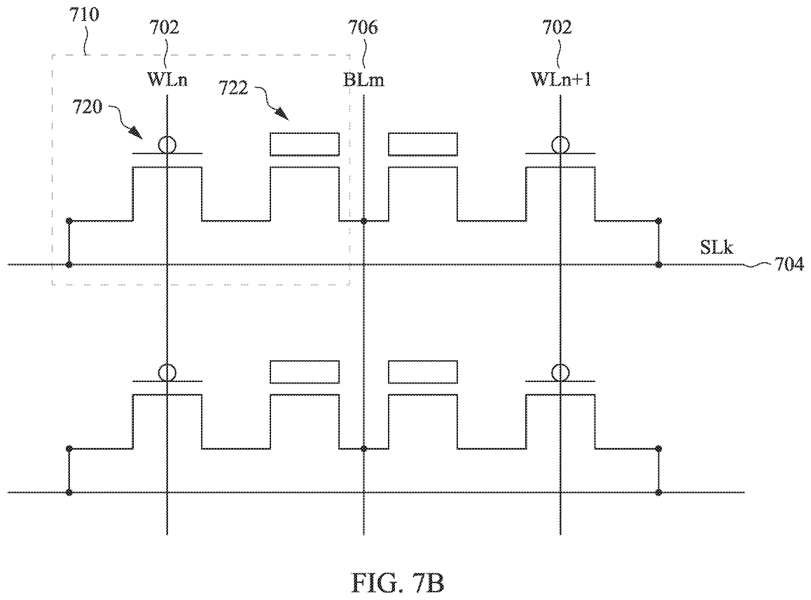

FIGS. 7A and 7B illustrate a NOR-type memory array arrangement using an OTP cell, according to certain embodiments. FIG. 7A illustrates a plan view of a NOR-type memory cell 700 utilizing an OTP cell, according to certain embodiments. FIG. 7B shows a schematic diagram illustrating the memory cell array 700 in accordance with some embodiments. Different voltage levels may be used for read operations as compared to program operations. The NOR-type memory cell 700 can include select gates 702, source lines 704 (SL) and bit lines 706 (BL). The select gate can work as word line (WL). In the example shown in FIGS. 7A and 7B, a memory cell 710 can include a select transistor 720 and a Storage gate storage device storage element 722. The transistor 720 can be used as an access element, whereas the Storage gate storage device storage element 722 can be used as a storage element that stores information (e.g., a “logic 0” or a “logic 1”). In some embodiments, two neighboring cells may be merged to form one BL in order to increase memory density. It should be understood that the example shown in FIGS. 7A and 7B is exemplary rather than limiting, and the memory device may include other components and functions in other embodiments.

Table 1 shows operation voltage of the NOR-type memory cell 700. Different voltage levels may be used for reading and programing operations. The voltages can be optimized by characterizing the OTP cell.

TABLE 1

| | Read | Program |
|---|---|---|
| WLn | −Vdd | −Vdd2 |
| WLn + 1 | 0 V | 0 V |
| BLm | − Vdd | −Vdd2 |
| SLk | 0 V | 0 V |
| SLk + 1 | − Vdd | −Vdd2 |

In various embodiments, Vdd can have a value of 1.0 V to 10.0, while in other embodiments Vdd can have a value of 3.0 V to 8.0V, and in yet other embodiments Vdd may have a value of 5.0 V to 7.0 V. In some embodiments, Vdd2 can have a value of 1.0 V to 10.0, while in other embodiments Vdd2 can have a value of 3.0 V to 8.0V, and in yet other embodiments Vdd2 may have a value of 5.0 V to 7.0 V. As appreciated by one of ordinary skill in the art having the benefit of this disclosure, values for Vdd and Vdd2 can be set to any suitable value.

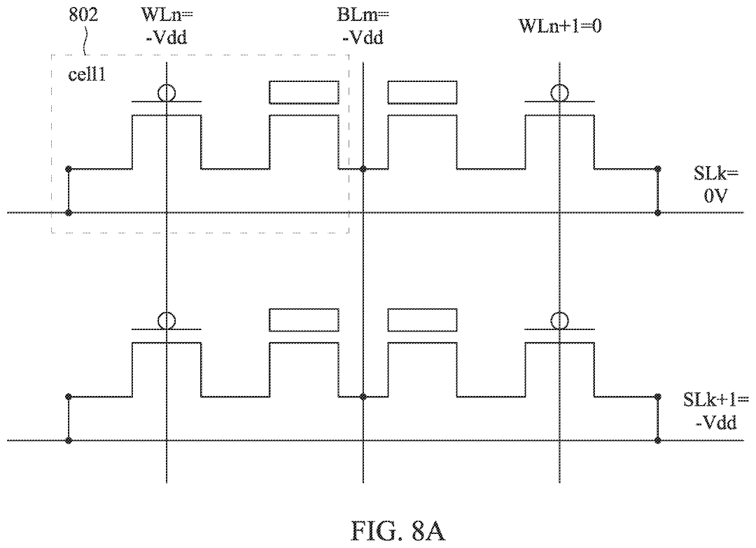

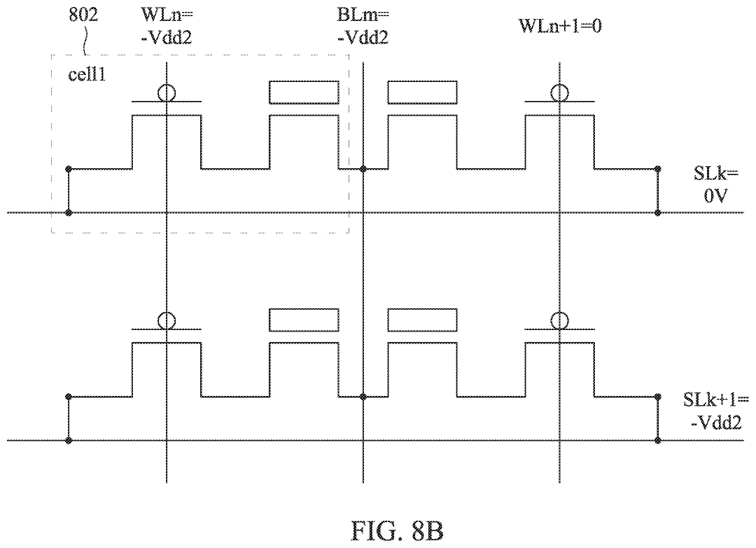

FIGS. 8A and 8B illustrate read and program operation of the memory cell 710, according to certain embodiments. As shown in FIG. 8A, in a read operation of the memory cell 802, a voltage on the WLn is high (−Vdd), a voltage on the BLm is high (−Vdd), a voltage on the WLn+1 is 0.0, a voltage on SLk is 0.0, and a voltage on SLk+1 is −Vdd. Vdd is a first voltage and Vdd2 is a second voltage. In this way, only memory cell 802 is read and the adjacent three cells are not read. As shown in FIG. 8B, in a programming operation of the memory cell 802, a voltage on the WLn is −Vdd2, a voltage on the BLm is −Vdd2, a voltage on the WLn+1 is 0.0, a voltage on SLk is 0.0, and a voltage on SLk+1 is −Vdd2, Vdd2 is a second voltage. In this way, only cell 802 is programmed and the adjacent three cells are not programmed. It should be understood that the example shown in FIGS. 8A and 8B is exemplary rather than limiting, and the memory device may include other components and functions in other embodiments.

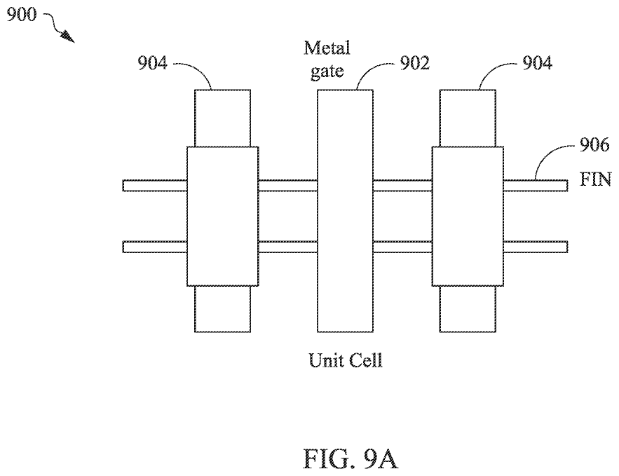

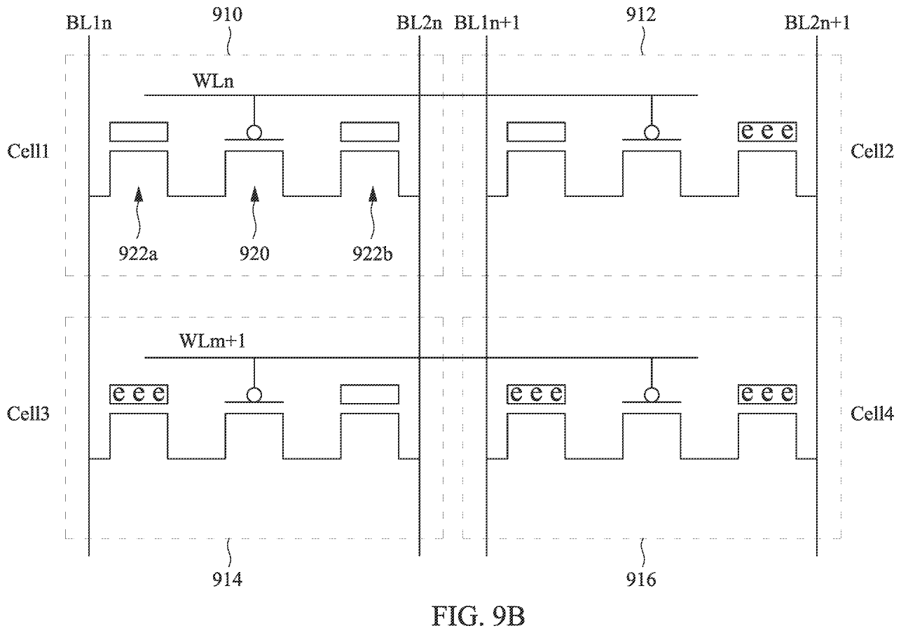

FIGS. 9A and 9B illustrate an AND-type memory array arrangement using an OTP cell, according to certain embodiments. FIG. 9A illustrates a plan view of a AND-type memory cell 900 utilizing an OTP cell, according to certain embodiments. FIG. 9B shows a schematic diagram illustrating the AND-type memory cell 900 in accordance with some embodiments. The AND-type memory cell 900 can include select gate 902, source lines 904 (SL) and bit lines 906 (BL). The select gate can work as word line (WL). In the example shown in FIG. 9B, a memory cell 910 can include a select transistor 920 and two Storage gate storage device storage elements 922a and 922b. The transistor 920 can be used as an access element, whereas the Storage gate storage device storage elements 922a and 922b can be used as a storage element that can store information (e.g., a “logic 0” or a “logic 1”). The AND-type memory cell 900 can have one access element in the middle and a first storage element on the left and a second storage element on the right of the access element. In the way, a size of the memory cell can stay relatively small. In some embodiments, two neighboring cells may be merged to form one BL in order to increase memory density. Two bits of information can be stored on this AND-type memory cell. It should be understood that the example shown in FIGS. 9A and 9B is exemplary rather than limiting, and the memory device may include other components and functions in other embodiments.

Table 2 shows operation voltage of the AND-type memory cell 900 for a read condition for cells 910, 912, 914 and 916:

TABLE 2

| | | | Read 1 | | | | Read 2 | | | |
|---|---|---|---|---|---|---|---|---|---|---|
| | WLm | WLm + 1 | BL1n | BL2n | BL1n + 1 | BL2n + 1 | BL1n | BL2n | BL1n + 1 | BL2n + 1 |
| Cell 910 | −Vdd | 0 V | −Vdd | 0 V | 0 V | 0 V | 0 V | −Vdd | 0 V | 0 V |
| Cell 912 | −Vdd | 0 V | 0 V | 0 V | −Vdd | 0 V | 0 V | 0 V | 0 V | −Vdd |
| Cell 914 | 0 V | −Vdd | −Vdd | 0 V | 0 V | 0 V | 0 V | −Vdd | 0 V | 0 V |
| Cell 916 | 0 V | −Vdd | 0 V | 0 V | −Vdd | 0 V | 0 V | 0 V | 0 V | −Vdd |

In various embodiments, Vdd can have a value of 1.0 V to 10.0, while in other embodiments Vdd can have a value of 3.0 V to 8.0V, and in yet other embodiments Vdd may have a value of 5.0 V to 7.0 V. As appreciated by one of ordinary skill in the art having the benefit of this disclosure, values for Vdd can be set to any suitable value. There are two read operations involved, a first read operation (Read 1) and a second read operation (Read 2). During the first read operation, a state of the first storage element can be read and during the second read, a state of the second storage element can be read, as shown in Table 2.

Table 3 shows results of the read operation shown in Table 2, for memory cells 910, 912, 914 and 916:

TABLE 3

| | Read Current | |
|---|---|---|
| | Read 1 | Read 2 |
| Cell 910 | Low | Low |
| Cell 912 | Low | High |
| Cell 914 | High | Low |
| Cell 916 | High | High |

### SUMMARY

In accordance with some aspects of the disclosure, a non-volatile memory (NVM) device is provided. The non-volatile memory (NVM) device includes: a semiconductor substrate comprising a plurality of fin-type structures; a select transistor formed on the semiconductor substrate, the select transistor comprising a gate layer disposed over a first dielectric isolation layer that is positioned over a first section of the plurality of fin-type structures, wherein the select transistor is a P-channel metal oxide semiconductor (PMOS) transistor; and a storage device formed on the semiconductor substrate, the storage device comprising a storage gate layer disposed over a second dielectric isolation layer that is positioned over a second section on the plurality of fin-type structures, wherein the storage gate layer is arranged to trap charges and the storage device is a P-channel storage device; wherein the select transistor is coupled to the storage device; and wherein the first section of the plurality of fin-type structures is adjacent to the second section of the plurality of fin-type structures.

In accordance with some aspects of the disclosure, a method of fabricating a non-volatile memory (NVM) device is provided. The method includes: providing a semiconductor substrate having a sacrificial gate layer disposed over a plurality of fin-type structures, wherein a first dielectric isolation layer is positioned between the sacrificial gate layer and the plurality of fin-type structures; removing the sacrificial gate layer in a first region and in a second region; filling the first and second regions with a storage gate layer; planarizing the storage gate layer and the first and second regions; replacing the first dielectric isolation layer with a second dielectric isolation layer in regions outside of the second region; and replacing the sacrificial gate layer with a metal layer.

In accordance with some aspects of the disclosure, a NOR non-volatile memory (NVM) device is provided. The NOR non-volatile memory includes: a semiconductor substrate comprising a plurality of fin-type structures; a NOR memory array formed in the semiconductor substrate and comprising a plurality of memory cells arranged in a plurality of rows and a plurality of columns, wherein each of the plurality of memory cells consists of a select transistor and a storage device; a plurality of word lines electrically connected to the plurality of rows, respectively; a plurality of source lines electrically connected to the plurality of columns, respectively; and a plurality of bit lines electrically connected to the plurality of columns, respectively; and wherein: the select transistor is formed on the semiconductor substrate, the select transistor comprising a gate layer disposed over a first dielectric isolation layer that is positioned over a first section of the plurality of fin-type structures, wherein the select transistor is a P-channel metal oxide semiconductor (PMOS) transistor; and the storage device is formed on the semiconductor substrate, the storage device comprising a storage gate layer disposed over a second dielectric isolation layer that is positioned over a second section on the plurality of fin-type structures, wherein the storage gate layer is arranged to trap charges, and wherein the storage device is a P-channel storage device; the select transistor is coupled to the storage device; the first section of the plurality of fin-type structures is adjacent to the second section of the plurality of fin-type structures; and the storage device is arranged to be programed by an off-state current in the storage device.

The foregoing outlines features of several embodiments so that one of ordinary skill in the art may better understand the aspects of the present disclosure. One of ordinary skill in the art should appreciate that they may readily use the present disclosure as a basis for designing or modifying other processes and structures for carrying out the same purposes and/or achieving the same advantages of the embodiments introduced herein. One of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A non-volatile memory (NVM) device comprising:
a semiconductor substrate comprising a plurality of fin-type structures;
a select transistor formed on the semiconductor substrate, the select transistor comprising a gate layer disposed over a first dielectric isolation layer that is positioned over a first section of the plurality of fin-type structures, wherein the select transistor is a P-channel metal oxide semiconductor (PMOS) transistor; and
a storage device formed on the semiconductor substrate, the storage device comprising a storage gate layer disposed over a second dielectric isolation layer that is positioned over a second section on the plurality of fin-type structures, wherein the storage gate layer is arranged to trap charges, and wherein the storage device is a P-channel storage device;
wherein the select transistor is coupled to the storage device; and
wherein the first section of the plurality of fin-type structures is adjacent to the second section of the plurality of fin-type structures.

2. The NVM device of claim 1, wherein the first dielectric isolation layer comprises a high-κ dielectric material.

3. The NVM device of claim 2, wherein the first dielectric isolation layer comprises hafnium oxide, hafnium silicon oxide, hafnium silicon oxynitride, zirconium oxide, or hafnium dioxide-alumina alloy.

4. The NVM device of claim 1, wherein the storage device is arranged to be programed by an off-state current in the storage device.

5. The NVM device of claim 1, wherein the gate layer comprises tungsten, aluminum, titanium nitride or tantalum nitride.

6. The NVM device of claim 1, wherein the trapped charges are electrons.

7. The NVM device of claim 1, wherein the second dielectric isolation layer comprises hafnium oxide, hafnium silicon oxide, hafnium silicon oxynitride, zirconium oxide, or hafnium dioxide-alumina alloy.

8. The NVM device of claim 1, wherein the semiconductor substrate comprises silicon.

9. The NVM device of claim 1, wherein the storage device is arranged to store a bit of information.

10. A method of fabricating a non-volatile memory (NVM) device, the method comprising:
providing a semiconductor substrate having a sacrificial gate layer disposed over a plurality of fin-type structures, wherein a first dielectric isolation layer is positioned between the sacrificial gate layer and the plurality of fin-type structures;
removing the sacrificial gate layer in a first region and in a second region;
filling the first and second regions with a storage gate layer;
planarizing the storage gate layer and the first and second regions;
replacing the first dielectric isolation layer with a second dielectric isolation layer in regions outside of the second region; and
replacing the sacrificial gate layer with a metal layer.

11. The method of claim 10, wherein the first dielectric isolation layer comprises a high-κ dielectric material.

12. The method of claim 11, wherein the first dielectric isolation layer comprises hafnium oxide, hafnium silicon oxide, hafnium silicon oxynitride, zirconium oxide, or hafnium dioxide-alumina alloy.

13. The method of claim 10, wherein the metal layer comprises tungsten, aluminum, titanium nitride or tantalum nitride.

14. The method of claim 10, wherein the second dielectric isolation layer comprises a high-κ dielectric material.

15. The method of claim 10, wherein the second dielectric isolation layer comprises hafnium oxide, hafnium silicon oxide, hafnium silicon oxynitride, zirconium oxide, or hafnium dioxide-alumina alloy.

16. A NOR non-volatile memory (NVM) device, comprising:
a semiconductor substrate comprising a plurality of fin-type structures;
a NOR memory array formed in the semiconductor substrate and comprising a plurality of memory cells arranged in a plurality of rows and a plurality of columns, wherein each of the plurality of memory cells consists of a select transistor and a storage device;
a plurality of word lines electrically connected to the plurality of rows, respectively;
a plurality of source lines electrically connected to the plurality of columns, respectively; and
a plurality of bit lines electrically connected to the plurality of columns, respectively; and
wherein:
the select transistor is formed on the semiconductor substrate, the select transistor comprising a gate layer disposed over a first dielectric isolation layer that is positioned over a first section of the plurality of fin-type structures, wherein the select transistor is a P-channel metal oxide semiconductor (PMOS) transistor; and
the storage device is formed on the semiconductor substrate, the storage device comprising a storage gate layer disposed over a second dielectric isolation layer that is positioned over a second section on the plurality of fin-type structures, wherein the storage gate layer is arranged to trap charges, and wherein the storage device is a P-channel storage device;
the select transistor is coupled to the storage device;
the first section of the plurality of fin-type structures is adjacent to the second section of the plurality of fin-type structures; and
the storage device is arranged to be programed by an off-state current in the storage device.

17. The NOR NVM device of claim 16, wherein the first dielectric isolation layer comprises a high-κ dielectric material.

18. The NOR NVM device of claim 17, wherein the first dielectric isolation layer comprises hafnium oxide, hafnium silicon oxide, hafnium silicon oxynitride, zirconium oxide, or hafnium dioxide-alumina alloy.

19. The NOR NVM device of claim 16, wherein the trapped charges are electrons.

20. The NOR NVM device of claim 16, wherein the gate layer comprises tungsten, aluminum, titanium nitride or tantalum nitride.
